(19) United States
(12) Patent Application Publication
(10) Pub. No.: US 2025/0286472 A1
(43) Pub. Date: Sep. 11, 2025

(54) INVERTER WITH INTERMEDIATE CIRCUIT CENTER AND METHOD FOR MEASURING ISOLATION RESISTANCE BY MEANS OF CONTROLLED ASYMMETRY

(71) Applicant: SMA Solar Technology AG, Niestetal (DE)

(72) Inventor: Burkard Müller, Kassel (DE)

(21) Appl. No.: 19/220,601

(22) Filed: May 28, 2025

Related U.S. Application Data
(63) Continuation of application No. PCT/EP2023/083939, filed on Dec. 1, 2023.

(30) Foreign Application Priority Data
Dec. 1, 2022 (DE) 10 2022 131 915.6

(51) Int. Cl. H02M 7/483; G01R 27/02; G01R 31/42

(52) U.S. Cl. CPC H02M 7/483; G01R 27/025; G01R 31/42

(57) ABSTRACT

The application relates to a method for operating an inverter configured to exchange power between a DC side and an AC side. The inverter includes a bridge circuit and a divided intermediate circuit with at least two partial capacitances, arranged between the DC side and the bridge circuit. The method includes producing a first asymmetry of the partial capacitances relative to one another for generating a first potential position of DC potentials of the partial capacitances of the intermediate circuit relative to ground potential, setting the first potential position of the DC potentials of the partial capacitances of the intermediate circuit to a first setpoint value by varying the asymmetry, the first setpoint value being constant for a first period of time or modulated at a frequency which is at least 100 times lower than an AC frequency of the exchange power.

### REFERENCE TO RELATED APPLICATIONS

This application is a Continuation of International Application number PCT/EP2023/083939, filed on Dec. 1, 2023, which claims the benefit of German Application number 10 2022 131 915.6, filed on Dec. 1, 2022. The contents of the above-referenced Patent applications are hereby incorporated by reference in their entirety.

### FIELD

The application relates to a method for operating an inverter, which is configured to exchange electrical power between a DC side (DC: direct current/direct-current voltage) and an AC side (AC: alternating current/AC voltage) thereof.

The application also relates to a use of the method for measuring isolation resistance and to an inverter

### BACKGROUND

An inverter is a power electronic device that can convert electrical power from direct current to alternating current, or vice versa from alternating current to direct current. When converting alternating current to direct current, the inverter acts as a rectifier. When operating a DC source connected to an inverter on the DC side, a measurement of the isolation resistance of the DC source may be desirable and/or necessary for safety reasons, especially if the inverter can be connected to an AC network on the AC side.

Various devices and methods are known for measuring the isolation resistance of a DC source connected to an inverter on the DC side relative to ground potential. In the present case, a DC source generally refers to an electrical device that can be operated with direct voltage and that can deliver and/or receive electrical power in the form of direct current, i.e., can act as a source and/or as a load. A DC source can be, for example, a PV generator, a battery, for example, a vehicle battery, a DC bus, an electrolyzer, a fuel cell, etc. A key feature of such isolation resistance measurement methods is to, in a targeted fashion, shift the potential position of the DC source relative to ground potential and to record the resulting ground currents at different potential position shift values. The ground currents can be directly recorded by means of current sensors at the DC lines on the DC side between the inverter and the DC source or at the AC-side output of the connected inverter, or can be indirectly recorded by means of voltage sensors on suitably arranged resistors.

The DC source can be connected to an AC network via the inverter and supply electrical power to the AC network or take power from the AC network. If the inverter is galvanically isolated between its DC side and its AC side, for example, via a transformer, the potential shift on the DC side is in principle possible independently of the AC side. However, if the inverter is not galvanically isolated between its DC side and its AC side, e.g., if it is designed as a transformerless inverter, the potentials on the DC side and on the AC side are usually galvanically connected to one another so that a shift in the potential on the DC side is not easily possible without galvanically isolating the inverter from the AC network on the AC side.

In order to effectively distinguish between resistive ground currents and capacitive leakage currents using measurement technology, it is advantageous to make the potential shift on the DC side as low-frequency as possible or even quasi-stationary, i.e., for example, to raise the potential on the DC side relative to ground and hold it for a few seconds and then lower it relative to ground and hold it for a few seconds, wherein the change in the potential position of the DC source is, for example, a few V to a few 10 V at DC voltages of the DC source of, for example, a few hundred volts in each case.

WO 2014 079 775 A1 proposes to impress a zero sequence system on the AC output voltages provided by half-bridges of an inverter on the phases of the AC network. For so-called 2-level topologies, in which an intermediate circuit of the inverter on the DC side is designed as a two-pole circuit, i.e., it has only two voltage levels and in particular no center tap with a connection to the inverter bridge, the value of this zero sequence system corresponds directly to the potential shift of the DC source connected to the inverter on the DC side relative to ground. However, this method is not applicable for a multi-level inverter with a divided intermediate circuit, especially if a center tap of the intermediate circuit is temporarily connected to the switching node of the half-bridges at certain times, since the impression of a zero sequence system would then unevenly load the partial capacitances of the divided intermediate circuit. The method is also not applicable to inverters where the center tap of the divided intermediate circuit is connected to the neutral conductor, since naturally a zero sequence system could not be impressed thereon.

DE102020103839A1 describes a circuit arrangement for balancing a divided DC voltage intermediate circuit arranged between two DC terminals.

### SUMMARY

The disclosure is directed to a method for operating a multi-level inverter and a multi-level inverter comprising a divided intermediate circuit, in which the DC-side isolation resistance can be measured by means of DC-side potential shift.

In one embodiment, an inverter is configured to exchange electrical power between a DC side and an AC side thereof. The inverter comprises a bridge circuit and a divided intermediate circuit that is arranged between the DC side and the bridge circuit and comprises at least two partial capacitances. The bridge circuit comprises semiconductor switches and can convert electrical DC power into AC power, and/or vice versa. A method for operating the inverter comprises:
producing a first asymmetry of the partial capacitances relative to one another to generate a first potential position of DC potentials of the partial capacitances of the intermediate circuit relative to ground potential, and
setting the first potential position of the DC potentials of the partial capacitances of the intermediate circuit to a first setpoint value by varying the asymmetry, wherein, for a first time period, the first setpoint value is constant or is modulated at a frequency that is at least 100 times lower than an AC frequency of the exchange power.

The generated asymmetry leads to a shift in the potentials of the DC terminals of the inverter relative to ground and thus, among other things, to a modification of ground currents, which can be used to measure the isolation resistance of the DC source relative to ground. By setting the first potential position to the first setpoint value, a quasi-stationary state is set to ensure correct measurement given the capacitances involved. It is advantageous in one embodiment to continue to keep the each of the voltages of the partial capacitances higher than the peak voltage of an AC network that may be connected to the AC side of the inverter so that the inverter can continue to generate the AC voltage and exchange electrical power with the AC network in the desired form and quality.

In one embodiment, by modulating the first setpoint value at a low frequency, sufficient time is provided to measure values, which are characteristic of isolation resistance, for the inverter and/or for a system in which the inverter is located. In one embodiment, ground currents and thus isolation resistances to ground can be measured.

In one embodiment, an intermediate circuit with two partial capacitances comprises a center which can be connected to ground potential, for example, by being led out of the device as the neutral conductor of the inverter and connected to the AC network. A partial capacitance is arranged between the center and a DC terminal on the DC side. The other partial capacitance is arranged between the center and the other DC terminal on the DC side. In the case of an intermediate circuit with more than two partial capacitances connected in series, the total capacitance of the intermediate circuit between the two DC terminals is accordingly divided between the partial capacitances. An intermediate circuit with more than two partial capacitances can comprise more intermediate taps between its two DC terminals and a center which can be connected to ground potential. In an intermediate circuit with a center connected to ground potential, half of the partial capacitances are in series between the center and one of the DC terminals and the other half of the partial capacitances are in series between the center and the other of the DC terminals. Accordingly, such intermediate circuits, provided they are symmetrical, comprise a DC connection with positive voltage and a DC connection with a corresponding negative voltage of the same magnitude relative to the ground potential.

The DC connections of the intermediate circuit can be connected to the DC connections of the DC side of the inverter and thus to a DC source connected to the DC side of the inverter. One or both of the terminals of the DC side of the inverter can be connected directly or via a DC/DC converter to the respective DC terminals of the intermediate circuit, so that there is a fixed potential reference between the terminals of the DC input and the terminals of the intermediate circuit. If a divided intermediate circuit comprises a midpoint between its DC terminals and this midpoint is connected to ground potential, the two DC terminals in a symmetrical intermediate circuit are at respective potentials that are symmetrical to one another relative to the ground potential, one with a positive and one with a negative sign.

The described method makes it possible to shift the potential position of the DC connections of the intermediate circuit by means of an asymmetry between the partial capacitances of the intermediate circuit. If the two partial capacitances of the intermediate circuit are asymmetrically charged and the potential position of the center is kept at ground potential, the total potential of the intermediate circuit is shifted relative to ground potential, and the potentials of its two DC connections are also shifted relative to an intermediate circuit with symmetrically charged partial capacitances. The same applies if there are more than two partial capacitances. Here, too, the total potential of the intermediate circuit and thus the potentials of its DC connections shift relative to ground potential due to the asymmetry of the intermediate circuit.

The divided intermediate circuit is shifted to a first potential level by setting a first asymmetry of the intermediate circuit. This first potential level is adjusted to a first setpoint by varying the asymmetry and is either kept constant by maintaining the first setpoint for the first time period or is modulated at a frequency. The frequency is small, at least 100 times smaller than the AC frequency on the AC side of the inverter.

In one embodiment, the method further comprises:
producing a second asymmetry or a symmetry of the partial capacitances relative to one another to generate a second potential position of DC potentials of the partial capacitances of the intermediate circuit relative to ground potential.

The second asymmetry of the intermediate circuit can comprise an opposite sign to that of the first asymmetry, and the second potential position can be set to a second setpoint value for a second time period. As an alternative to the second asymmetry, a symmetry of the intermediate circuit can be set for a second time period by setting an asymmetry setpoint value to zero.

By such a targeted generation of the first and/or second potential position of the divided intermediate circuit, it is possible to perform measurements in a targeted fashion, for example, current and/or voltage measurements, on the inverter, which are suitable for determining an isolation resistance by calculating the set voltages and the measured currents in a manner known per se.

In one embodiment of the method involving modulation of the first potential position, the modulated first setpoint value for the potential position is set by modulating the asymmetry and changing the sign. For example, the asymmetry can have different half-waves with different signs. Various forms of modulation of the first setpoint value are conceivable, for example, a sinusoidal shape.

The method thus makes it possible to create a potential shift on the DC side of the inverter and thus of the DC source, which can be used to determine the isolation resistance, exclusively or including via a quasi-stationary asymmetry of the divided intermediate circuit of the inverter. For this purpose, the divided intermediate circuit is deliberately pulled into an asymmetrical state, and a potential position set as a result is maintained quasi-stationary, i.e., kept constant for at least approximately one second or several seconds or modulated at very low frequencies, i.e., with frequencies well below the mains frequency, for example, with less than 1 Hertz, so that the time course of the potential position has sufficiently long time periods with quasi-stationary values, in particular at the extreme points of the modulation function used.

In order to record a complex isolation resistance more effectively, i.e., an isolation resistance that comprises a network of resistances, capacitances and inductances and therefore has different real and imaginary parts for different frequencies, the setpoint value for the potential position is sinusoidally modulated in one embodiment. In one embodiment, the setpoint value for the potential position can be modulated with sine functions of different frequencies one after the other in order to be able to determine not only the real and imaginary parts of the isolation resistance at a certain frequency, but also the underlying component values of the resistances, capacitances and inductances. Alternatively, sine functions of different frequencies can be superimposed when modulating the setpoint value and thus the potential position.

The method can be implemented by means of balancing control for the partial capacitances of the intermediate circuit by setting the setpoint value for the balancing control to a desired first or second setpoint value, a so-called asymmetry setpoint value of, e.g., 50 volts, in contrast to the usual value of zero (=symmetrical intermediate circuit).

For example, it is possible to create the first and/or second asymmetry by directly redistributing charge within the divided intermediate circuit and to vary it in order to set the first and/or second potential position to the setpoint value. This can be done, for example, by means of a balancing circuit, for example, using a DC/DC converter connected to the intermediate circuit. The balancing circuit transfers charge between the partial capacitances of the intermediate circuit.

When the asymmetry is produced by direct redistribution of the charge, the potential position of the intermediate circuit terminals is determined exclusively by the asymmetry of the intermediate circuit. Instead of controlling the potential position to a setpoint value, in this case the asymmetry can also be directly controlled using an equivalent setpoint value, i.e., a setpoint value can be specified and modulated over time for the asymmetry so that the potential position is accordingly controlled.

Often, a balancing circuit suitable for direct redistribution is already provided in the inverter. In addition to its actual function, balancing the intermediate circuit, it can also be used, according to the application, to produce an asymmetry of the intermediate circuit in a targeted fashion. In one embodiment, the asymmetry is set by specifying a first or second setpoint value for the balancing circuit that is not zero. In particular, the first or second setpoint value can also be modulated. Through modulation, the setpoint value can take on different values over time.

Such a method can be implemented, for example, by an inverter comprising an intermediate circuit balancing circuit by setting the setpoint value for the balancing circuit to a value other than zero. The center of the intermediate circuit can be connected to the N conductor and thus kept at ground potential so that the potentials of the DC terminals of the intermediate circuit and thus of the DC source are shifted, depending on the asymmetry set, with respect to a situation with a symmetrically charged intermediate circuit. The balancing circuit draws a current from one half of the intermediate circuit and supplies a different current to the other half of the intermediate circuit. These two currents are superimposed with the currents that are exchanged from the intermediate circuit via the DC side and/or the inverter bridge to form total currents, which, when integrated over time and divided by the intermediate circuit capacitance, result in the voltage of each intermediate circuit half. By varying the currents of the balancing circuit, the total currents can be influenced and thus the asymmetry of the intermediate circuit halves can be maintained or changed.

Alternatively or additionally, the asymmetry of the intermediate circuit and the first and/or second potential position of the DC potentials can be generated or maintained by interaction with the AC side of the inverter.

In a multi-level inverter, in which a center of the intermediate circuit is temporarily connected directly to a switching node of the half-bridges, the impression of a zero sequence system leads to an uneven load on the intermediate circuit halves and thus, when integrated over time, to an asymmetry of the intermediate circuit.

In one embodiment of the method, the bridge circuit initially produces the first and/or second asymmetry by the bridge circuit generating an initializing zero sequence system voltage, wherein the initializing zero sequence system voltage comprises a curve determined by means of a control process and generates an initial asymmetry of the intermediate circuit. The desired potential position is then set using a stabilizing zero sequence system voltage, which, in conjunction with the initial asymmetry caused by the initializing zero sequence system voltage, results in the desired potential position and also comprises a curve determined by means of a control process. Specifically, a controller can be used for this purpose to adjust the setpoint value for the potential position by changing the zero sequence system voltage as a manipulated variable. The first and/or second potential position is/are then set to the first and/or second setpoint value directly on this controller. The initializing and stabilizing zero sequence system voltages have different signs. The inverter bridge can generate the initializing and/or the stabilizing zero sequence system by generating a constant voltage offset on all the phase conductors and optionally on the N conductor relative to ground potential. If a specific inverter with a divided intermediate circuit already comprises a balancing controller which, with the aid of a zero sequence system impressed by individual voltages provided by the bridge branches, can create a suitable asymmetrical load on the intermediate circuit halves to reduce asymmetries, this balancing controller can be superimposed with the zero sequence system according to the application by giving the setpoint value for the balancing controller a finite value instead of the usual setpoint value of zero. Since the zero sequence system itself represents a manipulated variable for such superimposed control, it must be corrected; it is not sufficient to simply control the asymmetry.

Alternatively or additionally, the initial asymmetry can also be produced by initially loading the intermediate circuit asymmetrically, i.e., by exchanging different electrical powers with the partial capacitances. However, an initial asymmetry of the intermediate circuit produced either by the initializing zero sequence system or by the asymmetric load would amplify itself, particularly when electrical power from the DC source is input into the intermediate circuit and/or when electrical power is taken from the intermediate circuit and fed into an AC network by the inverter, and is therefore stabilized by the stabilizing zero sequence system in order to keep the desired asymmetry either constant for the first time period or to modulate it at a low frequency.

During operation as a rectifier, i.e., when electrical power is transferred from the AC side to the DC side of the inverter, an initially produced asymmetry of the intermediate circuit would be eliminated automatically during operation. Therefore, the desired asymmetry must also be stabilized during operation as a rectifier.

In one embodiment, the method using the zero sequence system voltage is used for inverters in which the center of the intermediate circuit comprises no connection to the N conductor of the AC network that can be connected on the AC side such that there is no fixed ground reference of the center of the intermediate circuit.

In one embodiment of the method, the zero sequence system voltages for setting the first potential position to a modulated setpoint value are each modulated at a frequency that is at least a factor of 100 lower than the frequency of the AC exchange power.

In an alternative embodiment, the zero sequence system voltages can also be largely constant at times, for example, for the first and/or second time period, for example, as soon as an adjusted equilibrium state of power flowing asymmetrically into the intermediate circuit and asymmetrically withdrawn from the intermediate circuit is reached, in order to set the first and/or second constant potential position. In this case, “largely constant” means that, the values are constant with the exception of fluctuations for correcting the first and/or second potential position. “Largely constant” can also be understood to mean that the zero sequence system voltages at least do not undergo a change of sign during the first and/or second time period. This facilitates each of the partial measurements at a certain quasi-stationary potential position.

Such an embodiment of the method can also be implemented, for example, by an inverter that does not comprise an intermediate circuit balancing circuit, by stabilizing an initial asymmetry by generating a stabilizing zero sequence system so that the first and/or second potential position specified by the setpoint value is set. A separate half-bridge can be provided for each output terminal L1, L2, L3 or N of the inverter. The asymmetry can also be “initialized” by generating the initializing zero sequence system, wherein the stabilizing zero sequence system for stabilizing the potential position—at least when the inverter is in operation—has an opposite sign than that of the initializing zero sequence system for initializing the asymmetry.

In one embodiment, the first and/or the second time period comprises at least 1 second, for example, several seconds.

In one embodiment, the first and/or second potential position is repeatedly periodically set, for example, repeated at low frequency. “At low frequency” means in this case that the frequency is at least 100 times lower than an AC frequency of the exchange power of the inverter.

It is possible to use the method to measure the isolation resistance of a DC source connected to the inverter on the DC side. For this purpose, the first potential position of the intermediate circuit is first set and a first ground current is recorded within the first time period or at a point in time in the first half-wave. The second potential position is then set and a second ground current is recorded within the second time period, or a second ground current is recorded at a time in the second half-wave of the modulated first potential position. The isolation resistance on the DC side of the inverter is then determined from the set potential positions and the measured ground currents using calculation operations that are known per se.

The DC terminals of the intermediate circuit, which correspond to the DC terminals on the DC side of the inverter, are each brought to their first or second potential position using the method. The DC terminals can be connected to the DC source. The potential position of the DC terminals then corresponds to the potential position of the DC terminals of the DC source if it is connected to the inverter on the DC side. The method thus allows continuous determination of an isolation resistance of a DC source, e.g., a direct current energy source, in particular a PV generator on the DC side of the inverter, while the inverter exchanges electrical power between its AC side and its DC side, e.g., to feed electrical power from a connected PV generator into a connected AC network. This can increase the safety of a PV system during operation.

An inverter is configured to exchange electrical power between a DC side and an AC side. The inverter comprises a bridge circuit and a divided intermediate circuit that is arranged between the DC side and the bridge circuit and comprises at least two partial capacitances. The inverter is configured to generate a first potential position of DC potentials of the partial capacitances of the intermediate circuit relative to ground potential. The first potential position is created by producing a first asymmetry of the partial capacitances relative to one another. The inverter is further configured to set the first potential level to a first setpoint value. The first setpoint value is kept constant or modulated at low frequency for a first time period. In one embodiment, “at low frequency” means a frequency that is at least 100 times lower than an AC frequency of the AC-side exchange power of the inverter.

The inverter can further be configured to generate a second potential position of DC potentials of the partial capacitances of the intermediate circuit relative to ground potential by producing a second asymmetry that has the opposite sign to that of the first asymmetry or a symmetry of the partial capacitances relative to one another. The inverter may further be configured to set the second potential position to a second setpoint value for a second time period, or to set the symmetry of the intermediate circuit to an asymmetry setpoint value of zero for a second time period.

In one embodiment, the inverter is configured to set the potential position by modulating the asymmetry and changing the sign in different half-waves to a modulated first setpoint value.

In one embodiment, the inverter comprises a device for redistributing charge within the divided intermediate circuit. The device for redistributing charge can, for example, be designed as a balancing circuit and arranged between the partial capacitances of the intermediate circuit. For example, the balancing circuit is designed as a DC/DC converter for transferring charges between the partial capacitances of the intermediate circuit.

Thus, the asymmetry can be produced by means on the DC side of the inverter, and the potential position of the DC potentials of the partial capacitances of the intermediate circuit relative to ground potential can be set according to the setpoint value by exchanging charge between the intermediate circuit halves, for example, using the balancing circuit. It is possible that the center of the intermediate circuit has a fixed reference to ground potential, for example through direct or indirect connection to the neutral conductor of an AC network connected on the AC side. If such a fixed potential reference exists between the center of the intermediate circuit and the neutral conductor of the AC network, especially if this connection is a direct one, the use of an intermediate circuit balancing circuit to produce the asymmetry of the intermediate circuit and to set the required potential positions is particularly advantageous in one embodiment.

In one embodiment, it is provided to connect a neutral conductor (N conductor) of an AC network that can be connected on the AC side via the inverter bridge circuit to a center of the intermediate circuit between a first partial capacitance and a second partial capacitance of the intermediate circuit.

In one embodiment, the inverter bridge circuit is configured to generate an initializing zero sequence system voltage, which shifts the potential position of the center of the intermediate circuit between the first and the second partial capacitances of the intermediate circuit relative to ground potential and asymmetrically loads the intermediate circuit. Such an initializing zero sequence system voltage can produce an initial asymmetry of the intermediate circuit, which, however, would continue to increase, especially if the sign of the initializing zero sequence system remained the same.

In one embodiment, the bridge circuit is therefore configured to generate a stabilizing zero sequence system voltage, which also shifts the potential position of the center of the intermediate circuit relative to ground potential and asymmetrically loads the intermediate circuit, but with the opposite sign to that of the initializing zero sequence system. The stabilizing zero sequence system voltage can influence the first and/or second asymmetry of the intermediate circuit and set and stabilize the potential position to the required setpoint value. The initializing and stabilizing zero sequence system voltages comprise different signs, which stabilizes the asymmetry of the intermediate circuit when the inverter is in inverting operation.

In the case of an inverter comprising more than two partial capacitances connected in series, i.e., more than three DC potentials in the intermediate circuit, for example a 5-level inverter with a four-part intermediate circuit with five voltage taps, the method can be correspondingly implemented, either by using an existing balancing circuit to generate the asymmetry and to set the potential position on more than two partial capacitances of an intermediate circuit, or by generating the zero sequence system.

The described method and the described inverter offer the advantage that at least the embodiments involving charge transfer between the partial capacitances are also applicable to inverters in which the center of the intermediate circuit is connected to the N conductor of an AC network. This allows continuous determination and thus permanent monitoring of the isolation resistance of a DC source connected to the inverter. In particular, monitoring can be carried out in a simple, cost-effective and reliable manner in a transformerless inverter. The embodiments that do not involve charge transfer between the partial capacitances of the intermediate circuit have the further advantage of not requiring a special balancing circuit.

### BRIEF DESCRIPTION OF THE FIGURES

The disclosure is further explained and described below with reference to example embodiments illustrated in the figures.

FIG. 1 shows a method for operating an inverter,

FIG. 2 schematically shows an embodiment of an inverter comprising a connected DC source and a connected AC network,

FIG. 3 schematically shows another embodiment of the inverter comprising a connected DC source and a connected AC network,

FIG. 4 schematically shows an equivalent circuit diagram of an embodiment of a divided intermediate circuit comprising a current source, and

FIG. 5 shows example time curves of voltages on the DC side of an inverter and of zero sequence system voltages when applying a method according to the application.

In the figures, identical or similar elements are denoted by the same reference signs. Representations in the figures may not be to scale.

### DETAILED DESCRIPTION

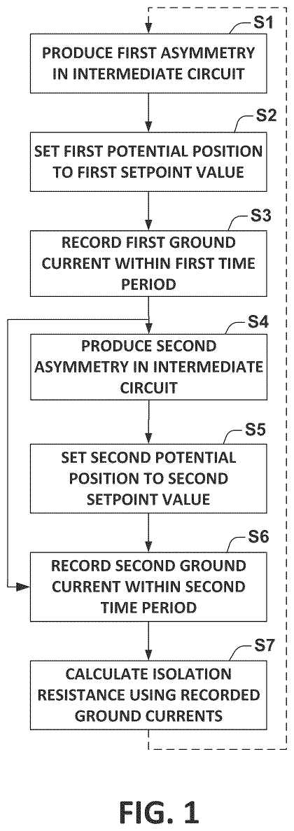

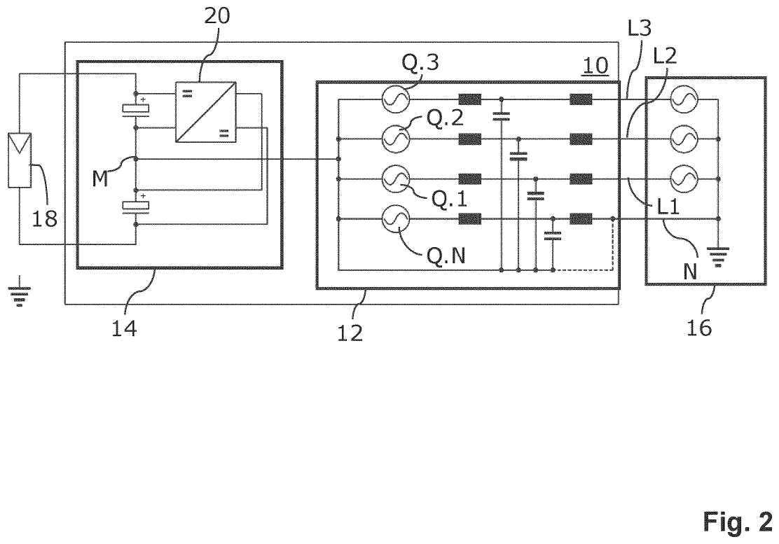

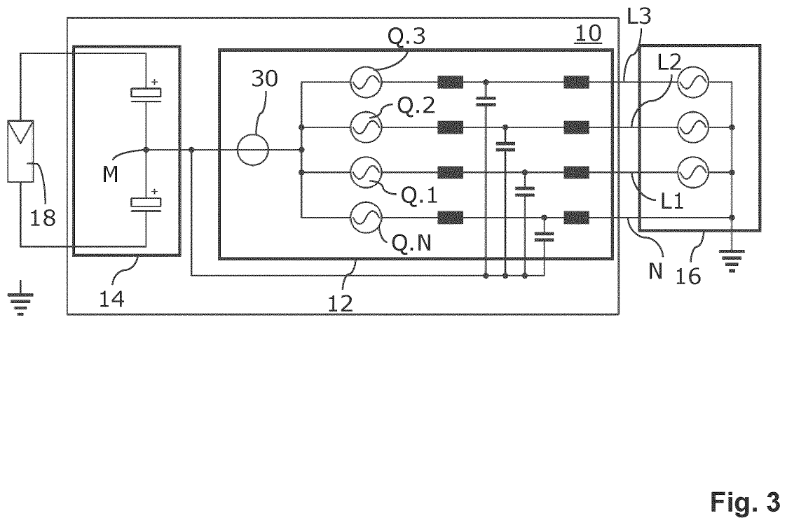

FIG. 1 schematically shows a method for operating an inverter 10 (cf. FIGS. 2 and 3), as can be used in a method for measuring isolation resistance. The inverter 10 is configured to exchange electrical power between a DC side and an AC side thereof. The inverter 10 comprises a bridge circuit 12 and a divided intermediate circuit 14 that is arranged between the DC side and the bridge circuit 12 and comprises at least two partial capacitances.

At S1, a first potential position of DC potentials of the partial capacitances of the intermediate circuit 14 relative to ground potential is created by producing a first asymmetry of the partial capacitances relative to one another. This can be done, for example, by the transfer of charge between the partial capacitances or by setting a zero sequence system voltage on the AC side of the inverter 10 (cf. FIGS. 2 and 3).

A divided intermediate circuit has a center node or tap M, and a respective partial capacitance is arranged between the center M and each corresponding DC terminal of the intermediate circuit. In one embodiment, the DC terminals of the intermediate circuit can correspond to the DC terminals on the DC side of the inverter 10. (See, e.g., FIG. 2). In the case of a DC source 18 connected on the DC side of the inverter 10, e.g., a photovoltaic generator, each DC potential of the divided intermediate circuit corresponds to a potential at a DC terminal on the DC side of the inverter 10 and thus of the DC source 18. If the center M is now kept at ground potential, an asymmetry of the intermediate circuit 14, i.e., an unequal charge and thus unequal voltage of the partial capacitances of the divided intermediate circuit 14, leads to a shift of the DC potentials of the DC terminals of the intermediate circuit 14 relative to ground potential.

At S2, the first potential position is set to a first setpoint value. The first setpoint value is kept constant for a first time period in one embodiment, or, in another embodiment is modulated at a frequency that is at least 100 times lower than an AC frequency of the exchange power of the inverter 10.

In an asymmetrically charged divided intermediate circuit 14, in which the center M is connected to ground potential or is kept at ground potential, the voltage distribution between the center M and the DC terminals of the intermediate circuit 14 is asymmetrical. This means that the center M is no longer in the middle of the two DC potentials of the DC terminals of the intermediate circuit. Hence the expression “asymmetry of the intermediate circuit 14.”

After setting the first potential position at S2, a first ground current is recorded at S3 within the first time period within which the first setpoint value is maintained, or at a point in time within the first half-wave of a modulated first setpoint value.

At S4, a second potential position of DC potentials of the partial capacitances of the intermediate circuit 14 relative to ground potential is created by producing a second asymmetry of the intermediate circuit, i.e., by producing an asymmetry of the partial capacitances relative to one another. Alternatively, symmetry of the intermediate circuit is produced at S4. Both can be achieved, for example, by transferring charge between the intermediate circuit parts or by setting a zero sequence system voltage on the AC side of the inverter 10 (cf. FIGS. 2 and 3).

At S5, the second potential position is set to a second setpoint value having the opposite sign to that of the first setpoint value for a second time period, or the symmetry of the intermediate circuit is set to a second setpoint value of zero for a second time period.

After setting the second potential position at S5, the ground current is again recorded at S6 within the second time period. Alternatively, after recording the first ground current at a point in time within the first half-wave of the modulated first setpoint value (at S3), the second ground current is then recorded at S6 at a point in time within the second half-wave of the modulated first setpoint value. For a modulated first setpoint value of the asymmetry of the intermediate circuit 14, separately setting the second potential position at acts S4 and S5 can therefore be dispensed with and S6 can be carried out immediately after S3.

After S6, the isolation resistance is then calculated in S7 from the set potential positions and the recorded ground currents.

In embodiments, it is possible to repeatedly perform the isolation resistance measurement method during normal operation of the inverter 10. This is shown by the dashed arrow between S7 and S1 in FIG. 1.

In FIG. 2, an inverter 10 having a DC source 18 connected on the DC side and an AC network 16 connected on the AC side thereof is shown schematically. The AC network 16 is a three-phase AC network with a neutral conductor N and has the three AC phases L1, L2 and L3. The inverter 10 comprises a bridge circuit 12 which converts direct current into alternating current and/or vice versa. For this purpose, the bridge circuit, for example, comprises clocked semiconductor switches. In FIG. 2, the bridge circuit is shown as an equivalent circuit diagram and comprises phase-related equivalent power sources, Q.N, Q.1, Q.2 and Q.3. The equivalent circuit diagram simulates the electrical behavior of the suitably clocked bridge circuit. In the example shown, each phase L1, L2, L3, N is assigned an equivalent current power source. The neutral conductor N is assigned the backup power source QN. The phase conductor L1 is assigned the equivalent current source Q.1, the phase conductor L2 is assigned the equivalent power source Q.2, and the phase conductor L3 is assigned the equivalent power source Q.3. In one embodiment, each of the equivalent power sources Q.N, Q.1, Q.2 and Q.3 may comprise a bridge circuit, for example, a half-bridge having at least two clocked semiconductor switches.

The inverter 10 further comprises a divided intermediate circuit 14. The divided intermediate circuit 14 comprises two partial capacitances and a center tap or node M. The center tap or node M can optionally be connected on the AC side to the neutral conductor N of the AC network 16 (dashed line in FIG. 2). This allows the center tap or node M to be kept at ground potential.

A DC/DC converter 20 is arranged between the two partial capacitances of the intermediate circuit 14. The DC/DC converter is configured to transfer charge between the two partial capacitances. The DC/DC converter 20 can therefore act, in one embodiment, as a balancer between the two partial capacitances, e.g., set the most identical charge possible for the partial capacitances, if this is desired.

In one embodiment, the charge can also be shifted between the partial capacitances via the DC/DC converter 20 in order to produce an asymmetry of the intermediate circuit. An asymmetry means that the halves of the intermediate circuit 14 each have a different amount of electrical charge. The voltages of the partial capacitances are therefore different in an asymmetrical intermediate circuit. The DC/DC converter 20 can therefore act selectively as a balancing circuit and as an unbalancing circuit and, by transferring charge between the partial capacitances of the intermediate circuit, produce an asymmetry of the intermediate circuit and set a required potential position. For example, the DC/DC converter 20 can set the potential position to the first and/or the second setpoint value. By appropriately actuating the DC/DC converter, the first setpoint value can also be modulated.

Once an asymmetry has been generated, it would automatically increase (inverter operation, power transfer from DC to AC) or decrease (rectifier operation, power transfer from AC to DC) depending on the operating mode of the inverter 10 and should therefore be held by the balancing circuit (unbalancing circuit) in such a way that the potential position is kept at the desired value. For this purpose, the first or second setpoint value for the balancing circuit can be set to a desired asymmetry setpoint value, e.g., to 50 volts for a given total voltage of the intermediate circuit of, for example, 1000 V, in contrast to the value of zero for a symmetrical intermediate circuit.

In one embodiment, the isolation resistance of the connected DC source 18 can be determined by recording the ground current at each of the first potential position, the second potential position, and/or when the intermediate circuit is symmetrical.

FIG. 3 illustrates a further embodiment of the inverter 10. In the example shown, the intermediate circuit 14 of the inverter 10 does not comprise a balancing circuit. The center of the divided intermediate circuit 14 in the example shown in FIG. 3 is not connected to the neutral conductor N of the AC network 16 and therefore has no fixed ground reference. In addition, in FIG. 3 the inverter 10 is connected on the DC side to the DC source 18 and on the AC side to the AC network 16. The DC source 18 is, for example, a photovoltaic generator. For example, the AC network 16 is a three-phase AC network with a neutral conductor N. The first phase of the AC network is designated by L1, the second phase of the AC network is designated by L2, and the third phase of the AC network is designated by L3.

The bridge circuit 12 is shown as an electrical equivalent circuit diagram comprising sources Q.1, Q.2, Q.3 and Q.N and is configured to form a zero sequence system 30 in addition to the usual phase or outer conductor voltages. In the example shown in FIG. 3, the zero sequence system is represented in the electrical equivalent circuit diagram as the voltage source 30. By setting an initializing zero sequence system voltage, the intermediate circuit 14 can be loaded asymmetrically and thus brought into an asymmetric state. If the inverter 10 is operated in inverter mode, i.e., if it is operated in an operating mode in which electrical power is transferred from the DC side, for example, the DC source 18, to the AC side, for example, the AC network 16, an asymmetry generated, for example, by the zero sequence system 30 would amplify itself during operation, for example, due to an uneven distribution of the DC power flowing from the DC source into the intermediate circuit to the partial capacitances. After setting the initializing zero sequence system voltage, a stabilizing zero sequence system voltage is thus generated in a second step, which has the opposite sign to that of the initializing zero sequence system voltage. As a result, the intermediate circuit is loaded asymmetrically in the opposite direction to that of the asymmetrically incoming power on the DC side, and the asymmetry of the intermediate circuit is stabilized so that the potential position is set to the first setpoint value. By setting further initializing and then stabilizing zero sequence system voltages, the second potential position can then be set accordingly. Alternatively or additionally, the first asymmetry of the intermediate circuit 14 and thus the potential position can be modulated at low frequency at certain times, for example, by correspondingly modulating the zero sequence system.

The asymmetry generated by the respective initializing zero sequence system 30 can thus be stabilized by the AC-side generation of the stabilizing zero sequence system 30, and the potential position can thereby be set. The asymmetry in the intermediate circuit 14 leads to an uneven distribution of the incoming DC power to the partial capacitances. Therefore, the stabilizing zero sequence system 30 is generated and controlled in such a way that the uneven power flow into the partial capacitances (when using a DC source 18, e.g., PV generator (PV-photovoltaic)) is inversely compensated for as uneven power withdrawal from the intermediate circuit halves so that the asymmetry and thus the potential position remains constant. This can also be called an unbalancing controller.

It should be noted that the generation of the zero sequence system 30 is only possible if the center tap or node M is not directly connected to the neutral conductor N.

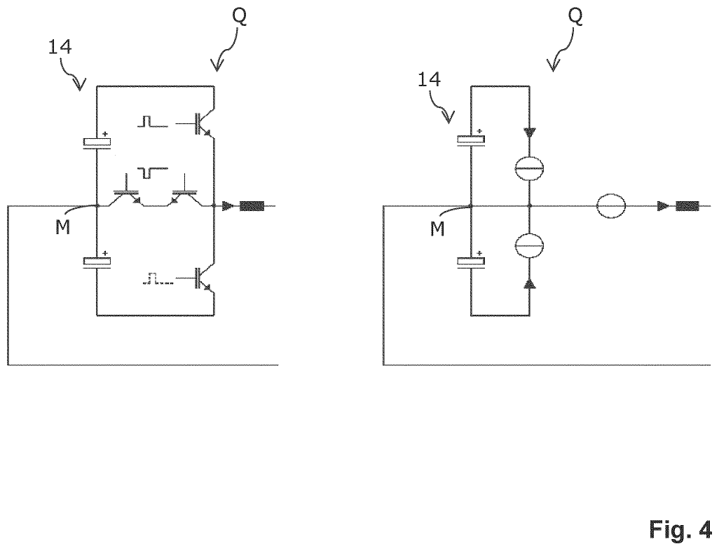

FIG. 4 shows two equivalent circuit diagrams of the intermediate circuit 14 with a connected 3-level half-bridge. On the left, examples of possible switches (here IGBTs) are shown, with which the switching node to the left of the inductor can be connected to the three taps of the intermediate circuit. By means of suitable activation of the semiconductor switches of the bridge circuit, a bridge circuit behavior can be generated which, on the output side, corresponds to the behavior of a voltage source Q, Q.1, Q.2, Q.3, Q.N on the conductors of the AC network. The voltage value of the voltage source results from the voltage of one intermediate circuit half multiplied by the duty cycle of the associated switch. The loads of the intermediate circuit halves can be represented by current sources whose value results from the inductor current multiplied by the duty cycle of the switch assigned to the intermediate circuit half. By appropriately actuating the bridge circuit 12, the zero sequence system voltage 30 can also be generated. In FIG. 4, the representations in the right and left halves are equivalent and each represent an electrical equivalent circuit diagram for the behavior of a bridge branch of the bridge circuit 12.

The generation of the zero sequence system 30 leads to a shift of the potential of the center tap or node M relative to ground potential that is undesirable per se and counteracts the asymmetry-induced potential shift. Therefore, the resulting DC-side potential shift tends to be smaller than the potential shift caused by the asymmetry of the intermediate circuit alone. The initial asymmetry due to the initializing zero sequence system feed 30 should therefore be greater than the potential shift of the center tap or node M induced by the stabilizing zero sequence system feed 30 necessary to stabilize the asymmetry.

Electrical three-phase systems can be described by so-called phasors. The phasors are divided into a symmetrical positive sequence system whose phasors move with the rotating field, a negative system with a rotating field in the opposite direction, and a zero sequence system. In the zero sequence system, the phasors of the different phases have the same direction and the same length. Zero systems occur in asymmetric three-phase systems.

The embodiment described with reference to FIGS. 3 and 4 can be used, for example, for inverters 10 in which the effort for a balancing circuit 20 is disproportionately large and in which all output terminals, phase conductors L1, L2, L3 and neutral conductor N are each provided by a separate half-bridge of the bridge circuit 12, so that the desired zero sequence system can be fed to the conductors of the AC network.

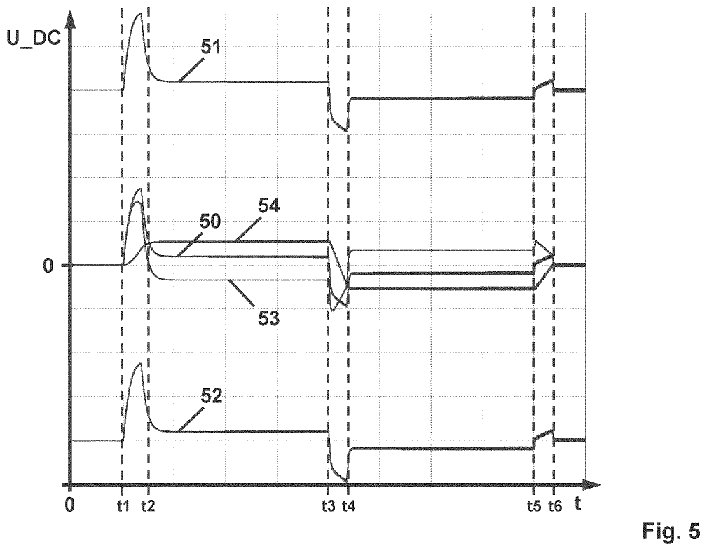

FIG. 5 shows, by way of example, the time courses of the potential positions of the DC potentials of the partial capacitances of an intermediate circuit relative to ground potential when carrying out a method according to the application for measuring isolation resistance using a zero sequence system voltage. The curve of the positive DC potential of the intermediate circuit is designated by reference sign 51 and the curve of the negative DC potential is designated by reference sign 52. In addition, reference sign 50 designates the curve of a virtual median potential of the intermediate circuit, i.e., the curve of the arithmetic mean between the DC potentials 51, 52. Furthermore, FIG. 5 shows the curve of the zero sequence system voltage by means of reference sign 53 and the curve of the resulting asymmetry of the partial capacitances of the intermediate circuit by means of reference sign 54.

In an initial situation at the time point t=0, the intermediate circuit is in a symmetrical state, i.e., the DC potentials 51, 52 have the same magnitude with different signs, and the virtual median potential 50 corresponds to the reference potential of the system, in particular ground potential, and by definition has a value of zero.

The method starts at the time point t1 with act S1 (cf. FIG. 1), in which a first potential position of the DC potentials 51, 52 of the partial capacitances of the intermediate circuit relative to ground potential is created by producing a first asymmetry of the partial capacitances relative to one another. For this purpose, an initializing zero sequence system is generated in the period between t1 and t2 by the zero sequence system voltage 53 assuming a positive value. As a result, the potential position of the intermediate circuit as a whole is initially raised so that the DC potentials 51, 52 and the virtual median potential 50 initially increase proportionally to the zero sequence system voltage 53. For a given power exchange from the intermediate circuit to the AC side of the inverter, the intermediate circuit is loaded asymmetrically due to this increase in the potential position and an asymmetry, i.e., a difference between the values for the DC potentials 51, 52, arises so that the asymmetry 54 increases; this can also be seen from the fact that the virtual median potential 50 exceeds the zero sequence system voltage 53 by the amount of the asymmetry 54.

At time t2, the asymmetry 54 has reached a target value and the zero sequence system voltage 53 returns to zero, since further asymmetric loading by an initializing zero sequence system is no longer necessary. At time t2, a first asymmetry thus exists, and the DC potentials 51, 52 are shifted from the initial state by the amount of the asymmetry 54 at the time point t2.

Subsequently, according to act S2 in FIG. 1, the potential position is set to a first setpoint value. If no zero sequence system were to be generated after time t2, the intermediate circuit would be asymmetrically charged due to the existing asymmetry by the inflow of electrical power from the DC source, and the asymmetry 54 would escalate. Therefore, a stabilizing zero sequence system is generated by setting the zero sequence system voltage 53 to a value with the opposite sign to that of the initializing zero sequence system between t1 and t2. As a result, the asymmetrical inflow of electrical power into the intermediate circuit is inversely compensated for by an asymmetrical withdrawal of electrical power from the intermediate circuit so that the asymmetry 54 remains constant. Since the stabilizing zero sequence system voltage in turn causes a shift in the potential position of the intermediate circuit as a whole, which is opposite to that of the shift caused by the asymmetry, a resulting potential position of the DC potentials 51, 52 occurs, which is shifted from the symmetrical initial position by the sum of the asymmetry 54 and the zero sequence system voltage 53, which is clearly visible at the position of the virtual median potential 50.

In the period between t2 and t3, a first measurement of a ground current is carried out according to act S3 from FIG. 1 and assigned to the specific values of the DC potentials 51, 52 at the stabilized first potential position.

At time t3, according to act S4 from FIG. 1, a second potential position of the DC potentials 51, 52 is produced by setting the asymmetry 54 to a value with the opposite sign. For this purpose, an initializing zero sequence system voltage is again generated, wherein the zero sequence system voltage 53 assumes a negative value such that the potential position of the intermediate circuit is lowered on the whole and the DC potentials 51, 52 and the virtual median potential 50 initially drop proportionally to the zero sequence system voltage 53. Due to this reduction in the potential position, the intermediate circuit is loaded asymmetrically and the asymmetry 54 decreases.

At time t4, the asymmetry 54 has reached a target value and the zero sequence system voltage 53 initially returns to zero so that at the time point t4 a second asymmetry exists and the DC potentials 51, 52 are shifted from the initial state by the amount of the asymmetry 54 at the time point t4. Subsequently, according to act S5 from FIG. 1, the potential position is set to a second setpoint value by generating a stabilizing zero sequence system, i.e., by setting the zero sequence system voltage 53 to a value having the opposite sign to that of the initializing zero sequence system between t3 and t4. The stabilizing zero sequence system is controlled by the zero sequence system voltage 53 so that the asymmetry 54 remains constant. This results in a second potential position of the DC potentials 51, 52, which is shifted from the symmetrical initial position by the sum of the asymmetry 54 and zero sequence system voltage 53, wherein the shift of the second potential position has an opposite sign to that of the shift of the first potential position.

In the period between t4 and t5, a second measurement of the ground current is carried out according to act S6 in FIG. 1 and assigned to the specific values for the DC potentials 51, 52 at the stabilized second potential position.

Based on the ground currents measured at the first and second potential positions, the isolation resistance on the DC side of the inverter can then be determined according to act S7 in FIG. 1.

After the measurement sequence is completed at the time point t5, the intermediate circuit can be brought into a symmetrical state and the potential position of the intermediate circuit can be returned to the initial state, which is reached at the time point t6. Alternatively, the method may be repeated by returning to act S1 according to FIG. 1 at the time point t5 or t6.

What is claimed is:

1. A method for operating an inverter which is configured to exchange electrical power between a DC side and an AC side thereof, wherein the inverter comprises a bridge circuit and a divided intermediate circuit that is arranged between the DC side and the bridge circuit and comprises at least two partial capacitances, the method comprising:
producing a first asymmetry of the partial capacitances relative to one another to generate a first potential position of DC potentials of the partial capacitances of the intermediate circuit relative to ground potential,
setting the first potential position of the DC potentials of the partial capacitances of the intermediate circuit to a first setpoint value by varying the asymmetry, wherein the first setpoint value is constant for a first time period or modulated at a frequency that is at least 100 times lower than an AC frequency of the exchange power.

2. The method of claim 1, further comprising:
producing a second asymmetry or a symmetry of the partial capacitances relative to one another to generate a second potential position of the DC potentials of the partial capacitances of the intermediate circuit relative to ground potential, wherein the second asymmetry has the opposite sign to that of the first asymmetry and the second potential position is set to a second setpoint value for a second time period or the symmetry of the intermediate circuit is set to an asymmetry setpoint value of zero for a second time period.

3. The method according to claim 1, wherein the modulated first setpoint value is set over time in different half-waves by modulating the asymmetry and changing the sign.

4. The method according to either claim 1, wherein the time course of the modulated first setpoint value comprises a plurality of different frequencies successively or superimposed.

5. The method according to claim 1, comprising:
producing and varying the first and/or the second asymmetry by redistributing charge within the divided intermediate circuit via a balancing circuit using a DC/DC converter, which transfers charge between the partial capacitances.

6. The method according to claim 5, comprising:
setting the first potential position by specifying a non-zero and optionally modulated asymmetry setpoint value for the balancing circuit.

7. The method according to claim 1, comprising:
producing the first and/or second asymmetry of the intermediate circuit by generating an initializing zero sequence system voltage by means of the bridge circuit,
setting the first and/or second potential position to the first and/or second setpoint by generating a stabilizing zero sequence system voltage using the bridge circuit,
wherein the initializing and the stabilizing zero sequence system voltage have different signs.

8. The method according to claim 7, wherein the zero sequence system voltages each comprise a modulation at a frequency which is at least a factor of 100 lower than the frequency of the AC exchange power, wherein the zero sequence system voltages are in particular sinusoidally modulated or are largely constant at certain times, in particular for the first and/or the second time period.

9. The method according to claim 1, wherein the first and/or the second time period comprises at least one second.

10. The method according to claim 1, wherein the setting of the first and/or the second potential position is repeated periodically.

11. The method according to claim 1 for measuring isolation resistance, comprising:
setting the first potential position and recording a first ground current within the first time period or at a time in the first half-wave,
setting the second potential position and recording a second ground current within the second time period, or
in the first potential position with modulated first setpoint value: recording the second ground current at a time in the second half-wave,
calculating the isolation resistance from the potential positions set and the ground currents measured.

12. An inverter which is configured to exchange electrical power between a DC side and an AC side thereof, wherein the inverter comprises a bridge circuit and a divided intermediate circuit that is arranged between the DC side and the bridge circuit and comprises at least two partial capacitances, wherein the inverter is configured to:
generate a first potential position of DC potentials of the partial capacitances of the intermediate circuit relative to ground potential by producing a first asymmetry of the partial capacitances relative to one another, and
set the first potential position to a first setpoint value, wherein, for a first time period, the first setpoint value is constant or modulated at a frequency that is at least 100 times lower than an AC frequency of the exchange power.

13. The inverter according to claim 12, wherein the inverter is further configured to generate a second potential position of the intermediate circuit relative to ground potential by producing a second asymmetry or a symmetry of the partial capacitances relative to one another, and to set the second potential position for a second time period to a second setpoint value or to set the symmetry of the intermediate circuit for a second time period to an asymmetry setpoint value of zero.

14. The inverter according to claim 12, wherein the inverter is further configured to set the first potential position to a modulated first setpoint value by modulating the asymmetry with changing sign in different half-waves.

15. The inverter according to either claim 12, wherein the inverter comprises a device for redistributing charge within the divided intermediate circuit, wherein the device for redistributing charge is designed in particular as a balancing circuit between the partial capacitances of the intermediate circuit.

16. The inverter according to claim 15, wherein the balancing circuit comprises a DC/DC converter configured to transfer charges between the partial capacitances.

17. The inverter according to claim 15, further comprising a neutral conductor of an AC grid connected on the AC side is connected via the bridge circuit to a center node of the intermediate circuit between a first partial capacitance and a second partial capacitance of the intermediate circuit.

18. The inverter according to claim 12, wherein the bridge circuit is configured to generate an initializing zero sequence system voltage, which shifts the potential position of a center node of the intermediate circuit between the first and the second partial capacitance of the intermediate circuit relative to ground potential.

19. The inverter according to claim 18, wherein the bridge circuit is configured to generate a stabilizing zero sequence system voltage, which shifts the potential position of the center node of the intermediate circuit relative to ground potential, wherein the initializing and the stabilizing zero sequence system voltages have different signs.

20. The inverter according to claim 18, wherein the bridge circuit is configured to set the potential position via the stabilizing zero sequence system voltage to the first or second setpoint value for the potential position, which is temporarily constant or modulated.
